(19) United States
(12) Patent Application Publication
(10) Pub. No.: US 2007/0059151 A1
(43) Pub. Date: Mar. 15, 2007

(54) Drum stand

(76) Inventor: Calvin C. Hager, Gun Barrel City, TX (US)

Correspondence Address: Stephen R. Greiner, Esquire;GREINER LAW OFFICES, P.C., Suite 110, 6701 Democracy Blvd., Bethesda, MD, 20817, US

(21) Appl. No.: 11/205,139

(22) Filed: Aug. 17, 2005

(51) Int. Cl. H01L 21/68

(52) U.S. Cl. 414/783

(57) ABSTRACT

A drum stand including a base having a pair of spaced-apart bearing plates, each of which has a notch in its top. A cradle, for receiving and supporting a drum, is removably positioned upon the base. The cradle includes a pair of lifting ears extending outwardly from the top thereof for engagement with the lifting arms of a forklift. The cradle also has a pair of axles below the lifting ears for rotatable positioning within the notch of a respective one of the bearing plates. A lock is provided for setting the angular relationship of the cradle relative to the base.

### FIELD OF THE INVENTION

The present invention relates generally to supports and, more particularly, to stands having tilting cradles.

### BACKGROUND OF THE INVENTION

It has always been difficult to dispense liquids from 55-gallon drums. Because of their great bulk, tipping drums to pour from access openings in their tops has been dangerous and likely to result in spills—undesirable events especially when the liquids are flammable or toxic. To make pouring easier, some have proposed stands for supporting drums above the ground at an incline. Unfortunately, getting the drums into these stands often requires the efforts of several men working together with one slip potentially resulting in a serious injury to one or more of the men. Thus, the drum stands developed in the past have not seen widespread acceptance in the field.

### SUMMARY OF THE INVENTION

In light of the problems associated with the known stands for use in supporting 55-gallon drums, it is a principal object of the invention to provide a stand into which a drum can be safely, easily, and quickly loaded by means of a conventional forklift. Once the drum is positioned in the stand, its inclination can be selectively varied to drain such completely at an optimum rate. After draining the drum, it can be removed from the stand without strain and replaced with a full one.

It is another object of the invention to provide a drum stand of the type described that is intuitive to use, requiring neither special tools nor prolonged training to set-up and operate.

It is an object of the invention to provide improved elements and arrangements thereof in a drum stand for the purposes described that is lightweight in construction, inexpensive to manufacture, and dependable in use.

Briefly, the drum stand in accordance with this invention achieves the intended objects by featuring a base having a pair of cradle braces connected together by crosspieces. Each of the cradle braces has a vertical member extending upwardly from a horizontal member and a bearing plate affixed atop the vertical member. Each bearing plate has a V-shaped notch in its top. A cradle, for receiving and supporting a drum, is removably and rotatably positioned upon the base. The cradle has a number of semi-circular ribs for engaging a drum. A pair of outside spars connects the ribs together and a strut connects the ends of the lowermost rib together. Two bands are hingedly secured to the outside spars for retaining a drum upon the strut and within the cradle. Two lifting ears are affixed to the tops of the outside spars for engagement with the lifting arms of a forklift. Two axles are affixed to the outside spars and are rotatably positioned within the V-shaped notches of the bearing plates. A lock is provided for setting the angular relationship of the cradle relative to the base.

The foregoing and other objects, features and advantages of the present invention will become readily apparent upon further review of the following detailed description of the preferred embodiment as illustrated in the accompanying drawings.

### BRIEF DESCRIPTION OF THE DRAWINGS

The present invention may be more readily described with reference to the accompanying drawings, in which:

FIG. 1 is a side perspective view of a drum stand in accordance with the present invention.

FIG. 2 is a front perspective view of the drum stand of FIG. 1.

FIG. 3 is a top view of the drum stand.

FIG. 4 is an enlarged perspective view of the top portion of one of the cradle braces of the drum stand.

FIG. 5 is an enlarged side view of portions of the mechanism for locking the cradle of the drum stand in an inclined relationship relative to the base of the drum stand.

Similar reference characters denote corresponding features consistently throughout the accompanying drawings.

### DETAILED DESCRIPTION OF THE PREFERRED EMBODIMENT

Referring now to the FIGS., a drum stand in accordance with the present invention is shown at 10. Stand 10 includes a base 12 for positioning upon the ground. A cradle 14, for grasping and carrying a 55-gallon drum 16, is pivotally supported by base 12 above the ground. In use, cradle 14 can be tipped to pour liquid from drum 16 and selectively detached from base 12 by means of a forklift (not shown) for the transportation of drum 16 over the ground.

Base 12 includes a pair of cradle braces 18 connected together by crosspieces 20 and 22. Each brace 18 has a horizontal member 24 from the center of which a vertical member 26 extends upwardly. Each brace 18 also has a bearing plate 28, provided with an upwardly opening, V-shaped notch 30 in its top, which is affixed to the top of its vertical member 26. Preferably, a pair of spaced-apart crosspieces 20 connect horizontal members 24 together and crosspiece 22 connects vertical members 26 together about ⅓ of the way up vertical members 26 to stabilize bearing plates 28.

Below its bearing plate 28, one of cradle braces 18 is provided with a retaining finger 32 defining part of a lock for use in selectively securing cradle 14 in one of a number of predetermined inclinations relative to base 12. The inner end of finger 32 is held by means of a pivot pin 34 to a retaining bracket 36 affixed to one of vertical members 26. Pivot pin 34 permits the movement of finger 32 from an elevated position, whereby the free, outer end of finger 32 is higher than the inner end of finger 32 through which pin 34 passes, to a lowered position, whereby the outer end of finger 32 is lower than the inner end of finger 32.

Cradle 14 includes three semi-circular ribs 38, 40 and 42 connected at their ends by a pair of outside spars 44. As shown, ribs 38 and 40 are respectively connected to the top and bottom of spars 44. Rib 42, however, is connected to spars 44 about ⅓ of the way from rib 38 to rib 40. An inside spar 46 connects the midpoints of ribs 38, 40 and 42 together so as to reinforce cradle 14. Further reinforcement of cradle 14, and a platform for drum 16, is afforded by a pair of parallel struts 48 and 50 connected to rib 40 with strut 48 joining the opposite ends of rib 40 together and strut 50 joining points on rib 40 located approximately midway between spars 44 and 46 together.

Ribs 38, 40 and 42 and spars 44 and 46 are dimensioned to snugly engage drum 16. Ribs 38, 40 and 42 have a radius of curvature that is substantially equal to that of drum 16. During use of stand 10, the opposite ends of ribs 38, 40 and 42 are located adjacent points that are 180° apart on the exterior of drum 16 for balanced loading. Spars 44 and 46, on the other hand, have heights that are substantially equal to the height of drum 16 thereby permitting ribs 38, 40 and 42 to engage drum 16 at widely spaced points for optimum stability.

Cradle 14 is provided with a pair of arcuate bands 55 for holding drum 16 within cradle 14. Each band 55 has a radius of curvature that is substantially equal to that of drum 16 and extends about ¼ of the way around drum 16 when drum 16 is positioned in cradle 14. The inner end of each band 55 is attached by means of a hinge 52 to a respective one of spars 44 at a point midway between ribs 38 and 42. The outer end of each band 55 is provided with an outwardly projecting flange 54 through which a threaded fastener 56 is passed to selectively lock the outer ends of bands 55 together around drum 16.

A pair of outwardly extending axles 58 and 60 is affixed to cradle 14 at the junctions of rib 42 and spars 44. Axles 58 and 60 are cylindrical rods dimensioned for smooth rotational movement within the bottoms of V-shaped notches 30 in bearing plates 28. Axles 58 and 60 are also constructed from materials having sufficient strength to support the weight of cradle 14 and drum 16 for indefinite periods of time. Preferably, axles 58 and 60 are welded to spars 44 at points located to the rear of the centerlines of spars 44 so that axles 58 and 60 are shifted rearwardly toward bands 55. This shift causes the top of cradle 14 and drum 16 to tip downwardly and forwardly a few degrees when first positioned upon base 12 thereby allowing easy access to the outlet 62 of drum 16.

End plates 64 and 66 to are affixed to the outer ends of axles 58 and 60 and radiate outwardly therefrom. End plates 64 and 66 serve to help position axles 58 and 60 within V-shaped notches 30 and, also, to prevent clothes, fingers, etc., from becoming inadvertently pinched between axles 58 and 60 and bearing plates 28. Plates 64 and 66 are shown to have semi-circular outlines, but can be provided with any suitable shape.

As is best seen with reference to FIG. 5, end plate 66 is provided with slots 68, 70 and 72 about its periphery that are oriented so as to radiate outwardly from axle 60. Slots 68, 70 and 72 are dimensioned to snugly, yet releasably, grasp the outer end of elevated retaining finger 32 that can pivot into a selective one of slots 68, 70 or 72 from below. When finger 32 is fitted into slot 68 at the bottom of plate 66, cradle 14 is held in a vertical orientation. However, when finger 32 is fitted into slot 70 in the front side of plate 66, cradle 14 is held in a horizontal orientation. Furthermore, when finger 32 is positioned in slot 72, located between slot 70 and the top of plate 66, cradle 14 is secured in an orientation where rib 38 at the top of cradle 14 is somewhat below rib 40 at the bottom of cradle 14.

A post 74 is affixed to axle 60 adjacent end plate 66. Post 74 extends upwardly at right angles to the longitudinal axis of axle 60. For convenience in manufacturing, post 74 may be formed from the same material as axles 58 and 60.

Rotational movement of cradle 14 upon axles 58 and 60 is facilitated by means of a tubular lever arm 76 whose inner end is slipped over post 74. Lever arm 76 is preferably hollow and dimensioned to provide sufficient torque about axles 58 and 60 to tip cradle 14 when pulled by a user of stand 10. When cradle 14 is being transported, as will be described hereinbelow, lever arm 76 can be disengaged from post 74 for storage in a convenient location. Later, when it is necessary to tip cradle 14, lever arm 76 can be selectively reattached to post 74 in a matter of seconds.

Struts 44 are provided with outwardly extending lifting ears 78 at their tops for use in hoisting and transporting cradle 14 and drum 16 positioned therein. Ears 78 are sized and spaced from one another so that a conventional forklift, without any modification of its structure, can with its lifting fork, engage the bottom of ears 78 and lift drum-laden cradle 14. For strength and stability, ears 78 project at right angles from struts 44 and are integrally formed with struts 44.

The use of drum stand 10 is straightforward. First, with cradle 14 detached from base 12 and sitting on the ground with bands 55 open and detached from one another, drum 16 is slid across struts 48 and 50 into engagement with ribs 38, 40 and 42. Next, if necessary, drum 16 is rotated such that its outlet 62 is directly adjacent inside spar 46. Then, bands 55 are closed against drum 16 and fastened together by extending threaded fastener 56 through flanges 54. Now, the cradle 14 and drum 16 can be lifted and transported together by a forklift.

The lifting of cradle 14 is accomplished in a matter of seconds by elevating the lifting arms of a forklift once they are positioned beneath ears 78 projecting outwardly from the top of cradle 14. With cradle 14 in an elevated position, it can be moved to a location directly above base 12 as illustrated in FIG. 2. Once there, cradle 14 is lowered such that axles 58 and 60 slide into the V-shaped notches 30 in bearing plates 28 with the relatively wide tops of notches 30 ensuring quick alignment. After being lowered into place, the force of gravity ensures that axles 58 and 60 do not become disengaged from bearing plates 28.

Upon disengagement of the forklift from ears 78, cradle 14 will automatically tilt forward a few degrees provided that axles 58 and 60 are attached to the rear edge of spars 44. With cradle 14 so tilted, lever arm 76 is easily engaged with post 74 so cradle 14 can be tilted to another orientation. Also, outlet 62 is threaded onto drum 16 so that its contents can be drained in a controlled manner.

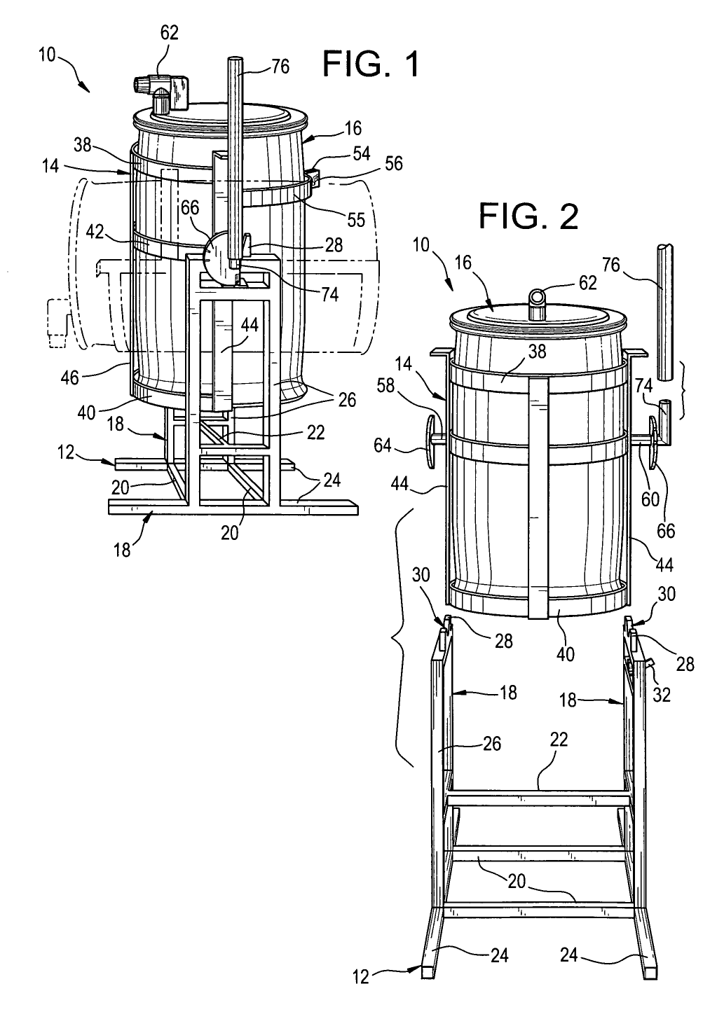

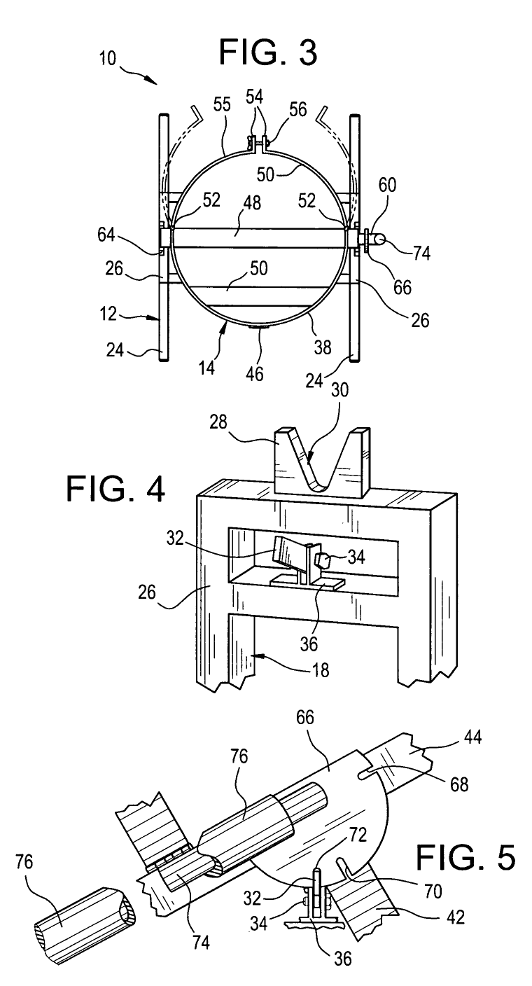

With suitable pressure being applied to lever arm 76, cradle 14 is moved so that it is placed in a vertical “storage” position as shown by solid lines in FIG. 1 or is inclined, perhaps to the horizontal “discharge” position illustrated by broken lines in FIG. 1. Once placed in a desired position, cradle 14 is locked in place by selectively positioning retaining finger 32 in one of the slots 68, 70 or 72 in end plate 66. Full drainage of drum 16 is accomplished by lowering outlet 62 to the degree permitted by engaging fmger 32 with slot 72. When drum 16 is empty, cradle 14 is moved to a vertical orientation for removal from base 12. Empty drum 16 is replaced with a full one by repeating the steps set forth above.

The entire process of positioning drum 16 within stand 10 requires just a few minutes to complete and is done in complete safety. Since stand 10 has few moving features, it is not subject to extensive wear and, if kept reasonably clean and protected from the elements, will last for generations.

While drum stand 10 has been described with a high degree of particularity, it will be appreciated by those skilled in the art that modifications may be made to it. For example, base 12 can be any structure capable of adequately supporting a pair of spaced-apart bearing plates 28 of the type specified. Furthermore, the number and location of slots 68, 70 and 72 provided in end plate 66 can be varied to suit the needs of a user. Therefore, it is to be understood that the present invention is not limited to the sole drum stand embodiment described above, but encompasses any and all embodiments within the scope of the following claims.

I claim:

1. A drum stand, comprising:
a base having a pair of spaced-apart bearing plates, each of which having a notch in its top;
a cradle, adapted to receive and support a drum therein, being removably positioned upon said base, said cradle including:
a pair of lifting ears extending outwardly from the top of said cradle, said lifting ears being adapted for engagement with the lifting arms of a forklift; and,
a pair of axles extending outwardly from said cradle below said lifting ears, each of said axles being rotatably positioned within said notch of a respective one of said bearing plates; and,
a lock for setting the angular relationship of said cradle relative to said base, said lock including:
a retaining finger being pivotally secured to said base adjacent one said notch; and,
an end plate being affixed to one of said axles and having a plurality of slots in the periphery thereof for snugly receiving said retaining finger.

2. A drum stand, comprising:
a base having a pair of spaced-apart bearing plates, each of which having a notch in its top;
a cradle, adapted to receive and support a drum therein, being removably positioned upon said base, said cradle including:
a plurality of semi-circular ribs for engaging the periphery of a drum, being positioned in a spaced-apart, yet stacked, relationship, each of said ribs having a pair of opposed ends;
a pair of outside spars connecting the respective ends of said ribs together;
a strut connecting the opposed ends of the lowermost one of said ribs;
a pair of lifting ears each being affixed to, and extending outwardly from, the top of a respective one of said outside spars, said lifting ears being adapted for engagement with the lifting arms of a forklift;
a pair of axles, each being affixed to, and extending outwardly from, a respective one of said outside spars below the tops thereof, each of said axles being selectively and rotatably positioned within said notch of a respective one of said bearing plates;
a lock for setting the angular relationship of said cradle relative to said base, said lock including:
a retaining finger being pivotally secured to said base adjacent one said notch;
and,
an end plate being affixed to one of said axles and having a plurality of slots in the periphery thereof for snugly receiving said retaining finger.

3. The drum stand according to claim 2 further comprising a lever arm being releasably attached to one of said axles for pivoting said cradle relative to said base.

4. A drum stand, comprising:
a base including:
a pair of cradle braces positioned side-by-side, each of said cradle braces including:
a horizontal member for positioning upon a supporting surface;
a vertical member extending upwardly from the center of said horizontal member; and,
a plurality of crosspieces connecting said cradle braces together;
a pair of bearing plates, each being affixed atop a respective one of said vertical members, each of said bearing plates having a V-shaped notch in its top;
a cradle, adapted to receive and support a drum therein, being removably positioned upon said base, said cradle including:
a plurality of semi-circular ribs for engaging the periphery of a drum, being positioned in a spaced-apart, yet stacked, relationship, each of said ribs having a pair of opposed ends;
a pair of outside spars connecting the respective ends of said ribs together;
a strut connecting the opposed ends of the lowermost one of said ribs;
a pair of bands, each being hingedly secured to a respective one of said outside spars for retaining a drum within said cradle;
a pair of lifting ears each being affixed to the top of a respective one of said outside spars, said lifting ears being adapted for engagement with the lifting arms of a forklift;
a pair of axles, each being affixed to, and extending outwardly from, a respective one of said outside spars below the tops thereof, each of said axles being selectively and rotatably positioned within said V-shaped notch of a respective one of said bearing plates;
a lock for setting the angular relationship of said cradle relative to said base, said lock including:
a retaining finger being pivotally secured to said base adjacent one said notch; and,
an end plate being affixed to one of said axles and having a plurality of slots in the periphery thereof for snugly receiving said retaining finger.
